(19) United States
(12) Patent Application Publication
(10) Pub. No.: US 2008/0277768 A1
(43) Pub. Date: Nov. 13, 2008

(54) SILICON MEMBER AND METHOD OF MANUFACTURING THE SAME

(75) Inventors: Masataka MORIYA, San Jose, CA (US); Kazuhiko Kashima, Tokyo (JP); Shinichi Miyano, Nariasaki-shi (JP)

Correspondence Address: FOLEY AND LARDNER LLP;SUITE 500, 3000 K STREET NW, WASHINGTON, DC, 20007, US

(73) Assignees: COVALENT MATERIALS CORPORATION; TOKYO ELECTRON LIMITED

(21) Appl. No.: 12/172,534

(22) Filed: Jul. 14, 2008

Related U.S. Application Data
(63) Continuation of application No. 11/339,564, filed on Jan. 26, 2006.

(30) Foreign Application Priority Data
Feb. 1, 2005 (JP) 2005-024686
Dec. 2, 2005 (JP) 2005-349297

(51) Int. Cl. H01L 27/00

(52) U.S. Cl. 257/655; 257/E27.001

(57) ABSTRACT

There is provided a silicon member that can prevent the resistivity of a member itself from varying in a semiconductor manufacturing process, in particular, in a plasma processing process, thereby making wafer processing uniform and being not an impurity contamination source to a wafer to be processed, and a method for manufacturing the same. The silicon member having a resistivity of 0.1 Ω·cm or more and 100 Ω·cm or less is manufactured with steps which are manufacturing a P-type silicon single crystal doped with 13 group atoms of a periodic table having an intrinsic resistivity of 1 Ω·cm or more and 100 Ω·cm or less, and changing said P-type silicon single crystal into an N-type silicon single crystal by oxygen donors formed by annealing at a temperature of 300° C. or more and 500° C. or less.

### CROSS-REFERENCE TO RELATED APPLICATIONS

The present application is a Continuation of U.S. application Ser. No. 11/339,564, filed Jan. 26, 2006, the entire contents of which are incorporated herein by reference, and is based upon and claims the benefit of priority from Japanese Patent Applications No. 2005-024686 filed on Feb. 1, 2005, and No. 2005-349297 filed on May Dec. 2, 2005, the entire contents of which are incorporated herein by reference.

### BACKGROUND OF THE INVENTION

1. Field of the Invention

The present invention relates to a silicon member that can be suitably used for plasma etching processing and heat treatment in a semiconductor manufacture.

2. Description of the Related Art

In a semiconductor manufacturing process, for example, a plasma etching apparatus shown in FIG. 1 is used in the process of forming a circuit pattern on a silicon wafer and an oxide film or a nitride film formed on the wafer is subjected to etching processing by producing plasma in a high-frequency electric field.

In a plasma etching apparatus 1 shown in FIG. 1, a wafer 2 is placed on a lower electrode 3 and a reactive gas 5 is supplied from the gas jet ports 4a of a shower plate (upper electrode) 4 and a high-frequency voltage is generated across the electrodes to produce a plasma to etch the surface of the wafer 2.

Here, to etch the wafer 2 uniformly, an electric field needs to be uniformly extended to the whole surface to be processed of the wafer 2, and hence a focus ring 6 is mounted on the periphery of the wafer 2.

The resistance of the above-mentioned focus ring 6 is determined to be a specified value under a standard so as to keep an electric field in a system constant. Then, the same material as the wafer to be processed, that is, a P-type silicon member is usually used for the focus ring 6 in terms of ease with which the electric field can be controlled and impurity contamination (for example, refer to Japanese Unexamined Patent Publication No. 2003-7686).

However, the P-type silicon member such as the above-mentioned focus ring are exposed to plasma environment along with the wafer to be processed and hence under the influence of the plasma and heat caused by the plasma, dopants such as boron in the P-type silicon become acceptors to make oxygen in the system donors.

As plasma etching processing is repeatedly performed, the oxygen donor gradually increase in number and hence an oxygen donor concentration in the silicon member increases and the resistivity of the silicon member increases to an infinity.

Then, when the oxygen donor concentration exceeds an acceptor concentration, the P-type silicon member is changed into a conduction type from a P type to an N type and behaves as an N type to cause a phenomenon in which the resistivity of the silicon member decreases.

Such a change in the resistivity of the silicon member as described above is frequently caused in a process to cause loss and variation in an electric field in the system to make wafer processing uneven to further cause a reduction in yield, which is not preferable.

To solve the above-mentioned problem, it is essential only that a material having its conduction type changed from a P type into an N type during a process is not used and hence it is thought that a silicon member including N-type silicon previously doped with arsenic or phosphorus is used.

However, the silicon member is etched in the process along with a wafer to be processed. Then, although the wafer to be processed is replaced sequentially but the silicon member is replaced at a lower frequency as compared with the wafer to be processed and hence is exposed to plasma environment for a long time and is increased in the amount of etching.

For this reason, there is apprehension that phosphorus or arsenic of the dopant of N-type silicon becomes an impurity contamination source to the wafer to be processed which is made of a P-type silicon single crystal.

Moreover, in recent years, as devices have become more complicated and more sophisticated, circuit patterns formed on wafers have become finer. Hence, it is required to etch the wafer in the pattern of a narrower width deeply and sharply. Therefore, in some cases, circuits are formed by sputtering as well as chemical etching.

Also in this sputtering, in the case of using an N-type silicon member, it is thought that there is a large possibility that phosphorus or arsenic of the dopant of the N-type silicon is expelled to become an impurity contamination source to the wafer to be processed.

Moreover, there is also presented a problem that when a silicon single crystal is pulled up out of the molten silicon liquid of a raw material, because the dopant of N-type silicon has a small partition coefficient as compared with a P-type dopant, an N-type silicon single crystal is inferior in manufacturing efficiency and hence is high in manufacturing cost, which results in increasing also the manufacturing cost of the N-type silicon member itself.

Therefore, it is desired not to use an N-type silicon member but to provide a silicon member that can be repeatedly used for a long time under plasma environment without changing the resistivity of a silicon member and does not have a detrimental effect such as impurity contamination on a wafer to be processed.

### SUMMARY OF THE INVENTION

The present invention has been made to solve the above-mentioned technical problems. The object of the present invention is to provide a silicon member that can prevent the resistivity of the silicon member itself from varying in a semiconductor manufacturing process, in particular, in a plasma processing process and hence can make wafer processing uniform and does not become an impurity contamination source to a wafer to be processed and the like, and a method for manufacturing the same.

A silicon member according to the present invention is characterized by including a silicon single crystal doped with 13 group atoms and having its conduction type changed from a P type into an N type by oxygen donors formed by annealing processing and having a resistivity of 0.1 Ω·cm or more and 100 Ω·cm or less.

Even when such a silicon member as described above is exposed to a plasma environment or a thermal environment of a temperature of from 400° C. to 500° C., because the silicon member is already changed in conduction type from a P type into an N type, it is possible to prevent the silicon member from varying in resistivity and to prevent wafer processing from being made uneven by the loss and variation of an electric field in the system of a semiconductor manufacturing apparatus and the like and further to contribute to an improvement in the yield of a device.

In this regard, the fact that the silicon single crystal is doped with 13 group atoms can be recognized by the qualitative and quantitative analysis of dopants, for example, by the use of a secondary ion mass spectroscopy (SIMS) method.

Moreover, the silicon member having its conduction type changed from a P type into an N type means a silicon member that is a silicon single crystal recognized to be doped with 13 group atoms and determined to be an N type by a thermoelectromotive method (heating probe method) or a point-contact current method, which is commonly used as a method for determining the conduction type of a semiconductor.

It is preferable that the above-mentioned silicon member has an oxygen concentration of 1×10¹⁸ atoms/cm³ or more and 2.5×10¹⁸ atoms/cm³ or less.

Here, an oxygen concentration referred to in the present invention is a value according to the old ASTM standards.

To produce a silicon member having its conduction type changed from a P type into an N type by annealing processing, it is preferable that an oxygen concentration is higher because when the oxygen concentration is higher, the silicon member is easily changed in an conduction type from a P type into an N type and hence time required to anneal the silicon member can be shortened. However, from a practical viewpoint as a member for a semiconductor manufacturing apparatus, it is preferable that an oxygen concentration is within the above-mentioned range.

Moreover, a method for manufacturing a silicon member according to the present invention is characterized by including A method for manufacturing a silicon member, comprising steps which are manufacturing a P-type silicon single crystal doped with 13 group atoms of a periodic table having an intrinsic resistivity of 1 Ω·cm or more and 100 Ω·cm or less, and changing said P-type silicon single crystal into an N-type silicon single crystal by oxygen donors formed by annealing at a temperature of 300° C. or more and 500° C. or less.

In the above-mentioned method for manufacturing a silicon member, a common P-type silicon single crystal is subjected to low-temperature annealing processing at a temperature of 300° C. or more and 500° C. or less, thereby being brought to the state of containing a specified concentration of oxygen donor, whereby a silicon member having its conduction type changed from a P type into an N type.

In the above-mentioned method for manufacturing a silicon member, from the viewpoint of easily controlling the intrinsic resistivity of the above-mentioned P-type silicon single crystal, the concentration of the doped 13 group atoms is 1×10¹⁴ atoms/cm³ or more and 1×10¹⁶ atoms/cm³ or less.

### BRIEF DESCRIPTION OF THE DRAWINGS

FIG. 1 is a cross-sectional view schematically showing one example of a plasma etching apparatus.

### DETAILED DESCRIPTION OF THE PREFERRED EMBODIMENTS

Hereinafter, the present invention will be described in more detail.

A silicon member according to the present invention is constructed of a silicon single crystal doped with 13 group atoms (B, Al, Ga, In, Ti), that is, a common P-type silicon single crystal doped with B, Ga, and the like and is changed in a conduction type from a P type into an N type by the formation of oxygen donor by annealing processing. Then, the silicon member is characterized by a resistivity of 0.1 Ω·cm or more and 100 Ω·cm or less.

In this manner, by making the resistivity of the silicon member 0.1 Ω·cm or more and 100 Ω·cm or less, an electric field in the plasma etching apparatus can be kept constant.

In this regard, the above-mentioned resistivity is a measurement value based on a four probe method in the standard of JIS H0602 (1995).

In the P-type silicon single crystal, under thermal environment at a low temperature of from 400° C. to 500° C., as described above, an oxygen donor concentration in the silicon member increases and the resistivity of the silicon member increases to an infinity. Further, when the oxygen donor concentration exceeds an acceptor concentration, there occurs a phenomenon in which the P-type silicon single crystal is changed into an N-type silicon single crystal and behaves as the N-type silicon single crystal and decreases in resistivity.

In the present invention, a silicon single crystal having previously changed in a conduction type from a P type into an N type and doped with 13 group atoms is applied to a semiconductor manufacturing apparatus, in particular, a plasma processing apparatus such as a plasma dry etching apparatus based on the above-mentioned phenomenon developing in an actual process.

That is, a silicon member according to the present invention is a common P-type silicon single crystal doped with 13 group atoms and is previously annealed to form oxygen donors, thereby being changed in a conduction type from a P type into an N type.

Therefore, when the silicon member according to the present invention is used as, for example, a member for plasma etching processing as is the case with the conventional P-type silicon member, even if the silicon member is exposed to a plasma environment or a thermal environment of from 400° C. to 500° C., because the silicon member is already changed in a production type from a P type into an N type, the silicon member is prevented from varying in resistivity and the wafer can be prevented from being unevenly subjected to etching processing by the loss or variation of an electric field in the apparatus, which results in contributing to an improvement in the yield of a device.

In this regard, in the above-mentioned silicon member, the fact that the silicon single crystal is doped with 13 group atoms can be recognized, for example, by the qualitative and quantitative analysis of dopants by the use of SIMS.

Moreover, the fact that the above-mentioned silicon member is changed in a conduction type from a P type into an N type can be recognized as follows: the silicon member is a silicon single crystal recognized to be doped with 13 group atoms by the SIMS, as described above, and is determined to be an N type by a thermoelectromotive method (heating probe method) or a point-contact current method, which is commonly used as a method for determining the conduction type of a semiconductor. These P/N type determining methods are test methods used also in the ASTM (American Society for Testing and Material) standards.

Moreover, it is preferable that the oxygen concentration of the silicon member according to the present invention is 1×10¹⁸ atoms/cm³ or more and 2.5×10¹⁸ atoms/cm³ or less.

As described above, to change a conduction type from a P type into an N type by annealing processing, it is preferable that an oxygen concentration is higher because when an oxygen concentration is higher, the silicon member is easily changed in the conduction type from a P type into an N type and time required for annealing processing can be shortened.

When an oxygen concentration is less than 1×10¹⁸ atoms/cm³, it is difficult to produce a silicon member that can keep resistivity constant within the above-mentioned range after the silicon member has its conduction type changed from a P type into an N type.

Meanwhile, it is practically difficult to form a silicon member having an oxygen concentration more than 2.5×10¹⁸ atoms/cm³ in the state of a single crystal.

The silicon member according to the present invention as described above can be produced by a manufacturing method according to the present invention, that is, with steps which are manufacturing a P-type silicon single crystal doped with 13 group atoms of a periodic table having an intrinsic resistivity of 1 Ω·cm or more and 100 Ω·cm or less, and changing said P-type silicon single crystal into an N-type silicon single crystal by oxygen donors formed by annealing at a temperature of 300° C. or more and 500° C. or less.

As for annealing processing, usually, at the time of manufacturing a wafer, high-temperature annealing processing is performed for donor killing processing, whereas in the silicon member according to the present invention low-temperature annealing is performed at a temperature of 300° C. or more and 500° C. or less, which is very different from the common annealing processing, because the silicon member needs to be in a state where the silicon member contains a specified concentration of oxygen donor so as to change its conduction type from a P type into an N type.

When the above-mentioned annealing processing temperature is less than 300° C., the efficiency of forming oxygen donors in the P-type silicon is lowered and hence it is very difficult to produce a desired oxygen concentration.

When the above-mentioned annealing processing temperature is more than 500° C., the donors of the silicon member are killed by high temperature and, also in this case, it is difficult to form oxygen donors in the P-type silicon.

The above-mentioned annealing processing temperature is preferably 400° C. or more and 500° C. or less.

Moreover, as described above, common P-type silicon doped with boron, gallium, or the like can be used as the P-type silicon single crystal doped with 13 group atoms before annealing processing but its intrinsic resistivity is preferably 1 Ω·cm or more and 100 Ω·cm or less.

Here, intrinsic resistivity means resistivity obtained by annealing a silicon single crystal at 650° C. for 30 minutes and then by cooling it by air to remove thermal donors (JIS H0602 (1995)).

When the initial resistivity of the P-type silicon is within the above-mentioned range, it is easy to control the resistivity of the silicon member obtained by annealing processing and showing resistance as an N type to a constant resistivity of 0.1 Ω·cm or more and 100 Ω·cm or less.

When the above-mentioned intrinsic resistivity is less than 1 Ω·cm, even when an oxygen donor concentration is increased, it is difficult to produce the above-mentioned silicon member by changing the conduction type of a silicon single crystal doped with 13 group atoms from a P type into an N type.

Meanwhile, the above-mentioned intrinsic resistivity is more than 100 Ω·cm, it is difficult to keep the guaranteed resistivity of the produced silicon member constant.

Then, such a silicon member is not practically used as a member for a semiconductor manufacturing apparatus used under a plasma environment and a low-temperature heat treatment environment.

Moreover, in the above-mentioned manufacturing method, it is preferable that the concentration of 13 group atoms doped into the above-mentioned P-type silicon single crystal is 1×10¹⁴ atoms/cm³ or more and 1×10¹⁶ atoms/cm³ or less.

In the common P-type silicon, by controlling a dopant concentration to within the above-mentioned range, it is easy to control its resistivity to within a range of 1 Ω·cm or more and 100 Ω·cm or less.

More preferable range of a dopant concentration to change the conduction type from a P type into an N type is 1×10¹⁴ atoms/cm³ or more and 3×10¹⁵ atoms/cm³ or less.

The above-mentioned annealing processing may be performed after the silicon material is formed into a desired shape such as a focus ring or may be performed to the silicon material shaped like a block at a preceding stage where the silicon material is not worked into a specified shape.

Time required to perform the above-mentioned annealing processing varies depending on the size of a desired member, a P-type dopant concentration, and a heat treatment temperature and is adjusted as appropriate. Then, since it is important for the whole silicon member to be uniform in resistivity, it is necessary to take sufficient time for that.

When the resistance of the silicon member varies from one portion to another, the portions function as capacitors and hence have detrimental effects on making an electric field uniform in the semiconductor manufacturing apparatus such as a plasma etching apparatus.

The silicon member according to the present invention produced in the above-mentioned manner can be suitably used as a focus ring in the above-mentioned plasma etching apparatus. However, the application of the silicon member according to the present invention is not limited to this but the silicon member according to the present invention can be suitably applied also to a member for a semiconductor manufacturing apparatus used under a plasma environment or a thermal environment (preferably, the plasma environment), other plasma apparatus, a heat treatment apparatus, and the like.

### EMBODIMENT

Hereinafter, the present invention will be described more specifically based on embodiment, but the present invention is not limited by the following embodiment.

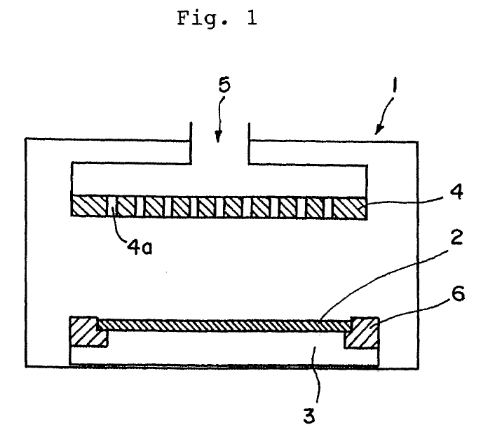

A P-type silicon single crystal doped with boron at a concentration of 1.72×10¹⁵ atoms/cm³ (having an intrinsic resistivity of 7.7 Ω·cm and a resistivity of 12.1 Ω·cm) was worked into a focus ring (having an outside diameter of 360 mm, an inside diameter of 302 mm, and a thickness of 5 mm), as shown in FIG. 1.

Thereafter, this was subjected to annealing processing under argon atmosphere at 470° C. for 15 hours, thereby being changed in its conduction type from a P type into an N type. In this manner, a focus ring made of an N-type silicon single crystal was manufactured.

The study of characteristics of the produced focus ring revealed that the focus ring had a resistivity of 2.7 Ω·cm and an oxygen concentration of 1.5×10¹⁸ atoms/cm³.

### EFFECT OF THE INVENTION

As described above, according to the silicon member of the present invention, it is possible to prevent the resistivity of the member itself from varying under a plasma environment and under a heat treatment environment at a low temperature of from approximately 400° C. to 500° C.

Therefore, it is possible to perform the wafer processing of the silicon member according to the present invention uniformly in a semiconductor manufacturing process. In addition, the use of P-type silicon member doped with 13 group atoms eliminates impurity contamination sources to a wafer to be processed and hence it is possible to suitably use the silicon member according to the present invention as a member for a semiconductor manufacturing apparatus, in particular, as a member for plasma processing and for heat treatment.

Moreover, according to the manufacturing method of the present invention, it is possible to provide a silicon member according to the present invention having the above-mentioned excellent features with comparative ease from commonly used P-type silicon.

What is claimed is:

1. A silicon member, comprising a silicon single crystal doped with atoms from group 13 of the periodic table and having its conduction type changed from a P-type into an N-type by oxygen donors formed by annealing processing and having a resistivity of from 0.1 Ω·cm to 100 Ω·cm.

2. A silicon member, comprising a silicon single crystal doped with atoms from group 13 of the periodic table and having its conduction type changed from a P-type into an N-type by oxygen donors formed by annealing processing and having a resistivity of from 0.1 Ω·cm to 100 Ω·cm and having an oxygen concentration of from 1×10¹⁸ atoms/cm³ to 2.5×10¹⁸ atoms/cm³.

3. A silicon member as claimed in claim 1, wherein the silicon member is prevented from varying in resistivity.

4. A silicon member as claimed in claim 1, wherein the whole silicon member is uniform in resistivity.

5. A silicon member for a semiconductor manufacturing apparatus, which is used in a processing container for containing and processing a semiconductor substrate, comprising a silicon single crystal doped with atoms from group 13 of the periodic table and having its conduction type changed from a P-type into an N-type by oxygen donors formed by annealing processing and having a resistivity of from 0.1 Ω·cm to 100 Ωcm.

6. A silicon member for a semiconductor manufacturing apparatus, which is used in a processing container for containing and processing a semiconductor substrate, comprising a silicon single crystal doped with atoms from group 13 of the periodic table and having its conduction type changed from a P-type into an N-type by oxygen donors formed by annealing processing and having a resistivity of from 0.1 Ω·cm to 100 Ω·cm and having an oxygen concentration of from 1×10¹⁸ atoms/cm³ to 2.5×10¹⁸ atoms/cm³.

7. A silicon member as claimed in claim 5, wherein the silicon member is prevented from varying in resistivity.

8. A silicon member as claimed in claim 5, wherein the whole silicon member is uniform in resistivity.
